(19) United States
(12) Patent Application Publication
(10) Pub. No.: US 2003/0234175 A1
(43) Pub. Date: Dec. 25, 2003

(54) Pre-sputtering method for improving utilization rate of sputter target

(75) Inventor: Twn-Ho Teng, Taoyuan Hsien (TW)

Correspondence Address: BRUCE H. TROXELL, SUITE 1404, 5205 LEESBURG PIKE, FALLS CHURCH, VA, 22041, US

(73) Assignee: HannStar Display Corp.

(21) Appl. No.: 10/421,789

(22) Filed: Apr. 24, 2003

(30) Foreign Application Priority Data
Jun. 25, 2002 (TW) 91113936

(51) Int. Cl. C23C 14/32

(52) U.S. Cl. 204/192.12

(57) ABSTRACT

A pre-sputtering method for improving utilization rate of targets, includes the steps of: providing a target; bombarding the target with ions; driving an elongated magnet to scan reciprocately at a constant speed to scan on the back side of the target during the bombarding process; and removing impurities from the surface of the target to complete the pre-sputtering for the target.

### FIELD OF THE INVENTION

The present invention relates to a method of pre-sputtering process and particularly a pre-sputtering method for improving the utilization rate of targets.

### BACKGROUND OF THE INVENTION

Sputtering is a semiconductor manufacturing process for depositing a metal film. The main principle of sputtering is to introduce plasma ions into the chamber of the sputter, then accelerate the ions to bombard a target to break away the atoms from the target surface (positive side) and to deposit a layer of metal film on the surface of a substrate.

FIG. 1 is a schematic view of a magnetic control scanning sputter 10, includes a chamber 11, a target 20, a base 13 and an elongated magnet 14. The chamber 11 is vacuumized to 1-10 mm torr by a vacuum pump (not shown in the drawing). Charged plasma ions, such as argon ions with positive charges, are introduced into the chamber 11. The target 20 includes a back plate 12 and a target material 16. The target 20 and the base 13 are connected to a negative electrode and a positive electrode respectively to form an electric potential gradient to drive the positive argon ions to bombard the target 20 so that the atoms of the target material 16 can be deposited on the base 13. A substrate 15, such as a wafer or a glass plate, is located on the surface of the base 13 to receive the atoms from the target material 16 to form a film. The elongated magnet 14 is located on the back side of the back plate 12 and is scanned reciprocaltely to control the uniformity and speed of the film deposited on the substrate 15.

FIG. 2 is a chart showing the relationship between moving distance and speed of the elongated magnet during the sputtering process. The scanning method is called “step variation speed method”. The scanning speed is accelerated stepwise from 160 mm/s to 340 mm/s and then to 350 mm/s. Thereafter, the scanning speed is decelerated to 340 mm/s and then to 160 mm/s. The elongated magnet scans at a predetermined speed of 350 mm/s at the most time for improving the uniformity of film deposited on the substrate. At this speed of 350 mm/s, the resistance (Rs) and film thickness have greater uniformity and better quality. However, according to the step variation speed method, the scanning speed is faster in the middle portion and slower at two ends during scanning, and the elongated magnet has a temporary pause effect in the reciprocal scanning process. Therefore, the erosion rate at the two ends is higher than that in the middle portion.

The operation techniques adopted in the step variation speed method are usually provided by the upstream equipment vendors. In most cases, the downstream manufacturers operate the sputter according to the instructions provided by the upstream equipment vendors. However, when the substrate undergoes the actual sputtering process, it generally goes through a pre-sputtering process for removing impurities from the target. Those impurities could be resulted from oxidization. In the pre-sputtering process, the object located on the base is a dummy substrate using for pre-sputtering, not the substrate using for sputtering.

However, equipment vendors usually suggest that the operation method (scanning speed) for the elongated magnet in the pre-sputtering process be same as that of the putter process, i.e. the “step variation speed method”. In the event that the pre-sputtering process also adopts the step variation speed method, due to the elongated magnet has a slower scanning speed at two ends of the scanning path and a temporary pause effect occurred at the returning points of the two ends, the target surface of the two ends also incur same kind of erosion as the sputter does, i.e. the erosion rate is faster at the two ends than the middle portion. As a result, the whole target surface does not have uniform erosion consumption in the pre-sputtering process.

Referring to FIG. 3, in the pre-sputtering process of the target 20, the target material 16 is eroded to a thickness d during the process removing the impurities from the middle portion of the target surface. Due to the slower scanning speed at the two ends and the temporary pause effect at the returning points, the two ends are eroded with a extra thickness d′ than the middle portion. When the sputter is carried out later and the target 20 is used continuously, if the elongated magnet still scans at the same speed (by step variation speed method), the target 20 is eroded with a faster erosion consumption at the two ends and result in eroded to the target back plate 12 faster. In another word, the target 20 is discarded faster. As most areas of the target 20 have a relatively low utilization rate, besides the two ends of the target material 16 of the target 20 that have excessive consumption, most of the middle portion of the target material 16 do not have much consumption and may last longer. But when the erosion consumption at the two ends of the target material 16 is approaching the target back plate 12, the target has to be discarded. It is a great waste to manufacturers. In addition, frequent replacement of the target 20 also increases maintenance time and labor cost.

Therefore in semiconductor manufacturing industry and to people in research and development, a lot of efforts and investments have been devoted to improve the pre-sputtering process and to overcome the problems encountered in the conventional techniques, with the goals to increase the utilization rate of the target, shorten pre-sputtering time and reduce waste of manpower.

### SUMMARY OF THE INVENTION

The primary object of the invention is to provide a pre-sputtering method to increase the utilization rate of the target that enables target material of the target be eroded and consumed uniformly in the pre-sputtering process and to prevent some areas of the target from being eroded excessively and resulting in dropping of the target utilization rate.

The pre-sputtering method of this invention includes the steps of: providing a target, then bombarding the target with ions. During the bombarding process, the elongated magnet is driven to scan at a constant speed reciprocately on the backside of the target until impurities on the target surface are removed. The pre-sputtering process is performed inside a chamber. The scanning speed of the elongated magnet is controlled between 140 mm/s and 200 mm/s. Preferably, the scanning speed of the elongated magnet is 160 mm/s. The above-mentioned speed is the initial scanning speed of the step variation speed method. In the pre-sputtering process, the substrate located on the base being used for forming film is a dummy substrate made of glass.

According to this invention, because the elongated magnet is scanning at a constant speed reciprocately on the back side of the target, the erosion consumption of the target is more uniform. Therefore, the excessive erosion occurred on some areas of the target surface is improved. As a result, target utilization is increased. Moreover, the scanning speed of this invention is slower than that of the conventional techniques. Therefore, more impurities is removed during each scanning operation. Otherwise, the moving frequency of the elongated magnet is lower, and total electric power consumption and target material consumption also are less. Usage of dummy substrate and maintenance and restart time are also decrease. Therefore the required material cost and labor cost of pre-sputtering also are reduced.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a magnetic control scanning sputter.

FIG. 2 is a chart showing the relationship between the moving distance and speed of the elongated magnet during sputtering process.

FIG. 3 is a schematic view showing the erosion consumption occurred on the surface of a target in the pre-sputtering process according to the conventional step variation speed method.

FIG. 4 is a flowchart showing the process of the pre-sputtering method according to this invention.

FIG. 5 is a chart showing the relationship between the moving distance and speed of the elongated magnet in the pre-sputtering process according to the invention.

FIG. 6 is a schematic view showing the erosion consumption occurred on the surface of a target in the pre-sputtering process that is performed at a constant speed according to the invention.

FIG. 7 is an analysis table showing the comparison results of pre-sputtering according to this invention and conventional techniques.

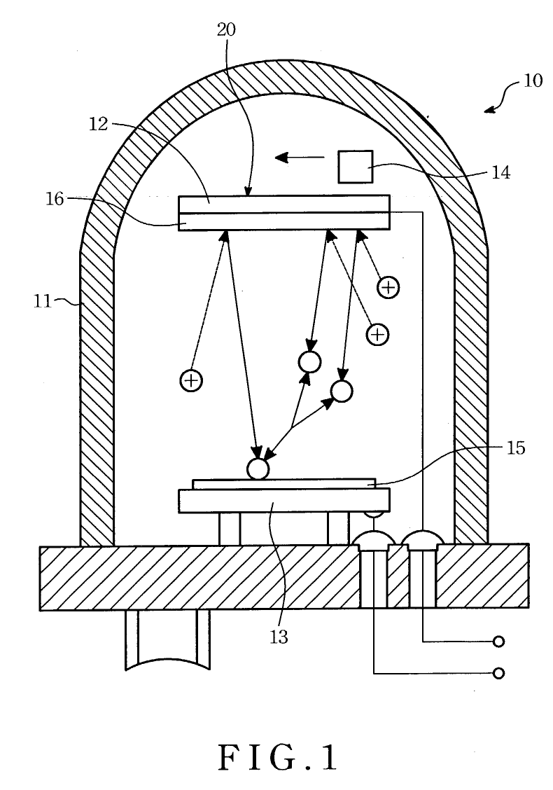

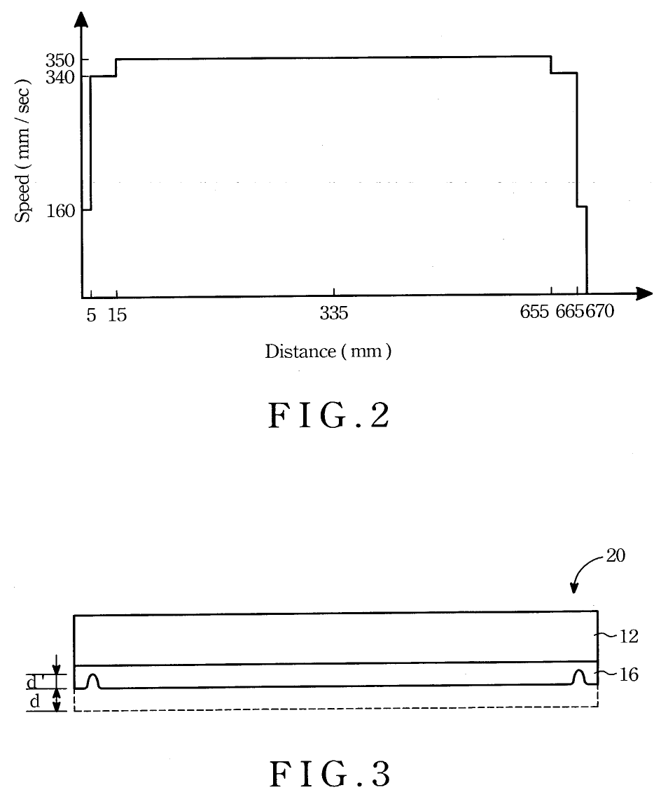

### DESCRIPTION OF THE PREFERRED EMBODIMENT

The pre-sputtering method for increasing target utilization rate of the invention aims at improving target utilization effectiveness, reducing electric power and target material consumption, decreasing consumption of dummy substrate and repairs and maintenance time. Details will be elaborated as follows:

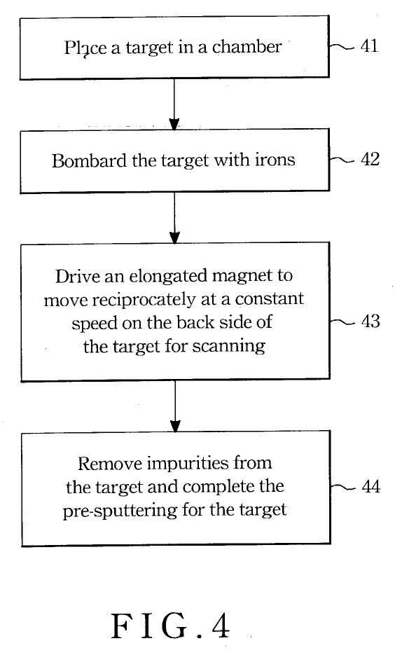

FIG. 4 is a flowchart showing of the pre-sputtering method according to this invention. First, a target is placed in a sputtering chamber (41), then plasma ions are introduced into the chamber and an electric potential gradient between the target and a base is formed by applying voltage to drive the plasma ions bombarding the target (42). During the bombardment, an elongated magnet is driven and scan reciprocately at a constant speed on the back side of the target (43) until impurities are removed from the target to complete the pre-sputter of the target (44).

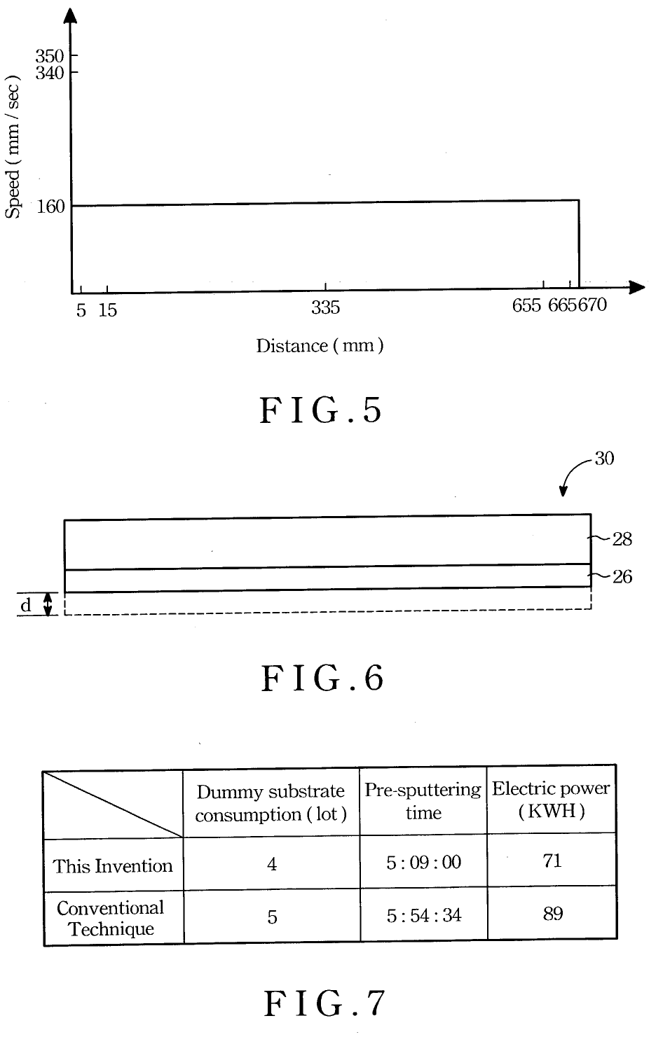

In the embodiment set forth above, the pre-sputtering machine is a sputter machine of Model SMD-650C made by ULVAC (Japan Vacuum). The pressure inside the chamber is controlled between 1 to 10 mm torr. The scanning speed of the elongated magnet is controlled between 140 mm/s to 200 mm/s, preferably is controlled at 160 mm/s. The speed is also initial speed adopted in the step variation method. FIG. 5 is a chart showing the relationship between the moving distance and speed of the elongated magnet. While the sputter machine model SMD-650C made by ULVAC (Japan Vacuum) has been used to do the pre-sputtering, it is by no means the limitation of the invention. Any other type of sputter machine could also be used in the method of this invention. The scanning speed range of 140 mm/s to 200 mm/s would be adjusted depending on individual machine type and still could achieve the desired effect of this invention. Moreover, in the pre-sputtering process, the substrate located above the base used for being deposited the film is a dummy substrate made of glass.

In step 43, the elongated magnet is moved at a constant speed to scan. It is mainly to resolve the problem of faster scanning speed in the middle portion and slower speed at the two ends that occurs to the elongated magnet in the conventional step variation speed method, and result in a faster erosion rate at the two ends of the target. In the previous discussions, the elongated magnet scans at a constant speed, and preferably scans at the speed of 160 mm/s in the step variation speed method. The mainly aim of this approach is to resolve the problem of the temporary pause effect occurred in the reciprocal scanning process. Because the speed of 160 mm/s is the initial scanning speed of the step variation speed method, the parameter adjustments and operation environment setups of the equipment have been tested and proved and the product can be prevented from undesirable impacting. Moreover, the invention employs the constant scanning speed of 160 mm/s adopted in the step variation speed method can reduce the temporary pause effect occurred to the elongated magnet in the returning process,

FIG. 6 is a schematic view showing the erosion consumption occurred on the target surface in the pre-sputtering process according to the invention. The target 30 consists of a target back plate 28 and a target material 26. The scanning speed of the elongated magnet is controlled between 140 mm/s to 200 mm/s, preferably is controlled at 160 mm/s. Compared with FIG. 3, it is clear that the erosion rate of the target material on the target surface that adopts the invention is more uniform than that in FIG. 3. For a target adopting the step variation speed in the pre-sputtering process, in the condition shown in FIG. 3, while the thickness of the target removed in the middle portion is d, the total thickness of the target removed at the two ends is d+d′ due to the effect incurred by the slower scanning speed and the temporary pause effect. This additional thickness d′ is the biggest disadvantage of the conventional pre-sputtering processes. And this invention can effectively overcome this disadvantage. According to this invention, by driving the elongated magnet at a predetermined scanning speed, the result as shown in FIG. 6 can be achieved. The thickness of the target material removed from the target is more uniformly distributed and the excessive erosion is not occurred. Thus the additional target material consumption of the thickness d′ at the two ends of the target is reduced. As a result, target utilization rate and life span is increased.

Based on previous discussions, it is clear that the invention is not only can reduce pre-sputtering time of the target, but also can reduce erosion consumption of the target material in the pre-sputtering process. In the pre-sputtering process, the sputter machine outputs the same electric power per unit time. Because the pre-sputtering time in this invention is reduced, total power consumption in the pre-sputtering process is also decreased. In addition, when the film deposited on the substrate surface exceeds a theoretical allowable safety thickness, the dummy substrate has to be discarded. As the target of this invention has less erosion consumption of target material in the pre-sputtering process, the thickness of the film deposited on the substrate surface is smaller. Therefore, the target material consumption at the two ends of the target is reduced, and the usage rate of the dummy substrate is increased.

FIG. 7 is an analysis table showing the comparison results of the pre-sputtering according to this invention and conventional techniques. According to conventional techniques, to complete pre-sputtering of a target requires five hours and fifty four minutes and thirty four seconds. Five lots of dummy substrates are consumed and total power is 89 KWH. According to this invention, time consumption is five hours and nine minutes, dummy substrates consumption is four lots, and total power consumption is 71 KWH. Each lot includes 24 pieces of dummy substrates. Overall, compared with the conventional techniques, this invention saves more than 20% of the dummy substrates consumption, power and pre-sputtering time. Thus this invention is not only can reduce costs, but also can increase target utilization rate.

The scanning speed of the elongated magnet in the pre-sputtering process of this invention is not restricted in the range of 140 mm/s and 200 mm/s. As long as conformed to the principle of constant speed scanning, the excessive erosion consumption at two ends of the target could be improved. On the other hand, the lower the scanning speed of the elongated magnet is, the greater erosion consumption of the target happens. However, such a phenomenon can reduce the reciprocal scanning frequency of the elongated magnet. This invention adopts the constant scanning speed of 160 mm/s in the step variation speed method mainly based on the consideration that because it is the initial scanning speed of the step variation speed method, parameter adjustment and operation environment setup of the equipment have been tested and proved so that undesirable impact to the product could be prevented from happening. Therefore, in this invention, the scanning speed is set in the range of 140 mm/s to 200 mm/s, and preferably is set at 160 mm/s. Of course, the foregoing speed range does not serve as the limitation of the invention. Adjustments and modifications would be made according to actual requirements.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A pre-sputtering method for improving utilization rate of targets using in a chamber, comprising steps of:
providing a target;
bombarding the target with ions;
driving an elongated magnet to scan at a constant speed on a back side of the target reciprocately; and
removing impurities from the target to complete the pre-sputtering for the target.

2. The pre-sputtering method of claim 1, wherein the pressure of the chamber is 1 to 10 mm torr by using a vacuum pump.

3. The pre-sputtering method of claim 1, wherein the scanning speed of the elongated magnet is 140 mm/s to 200 mm/s.

4. The pre-sputtering method of claim 1, wherein the scanning speed is 160 mm/s.

5. A pre-sputter for improving utilization rate of target, comprising:
a chamber, having a base for a substrate located thereon;
a target, placed in said chamber, wherein an electric potential gradient is formed between said target and said base;
a plurality of plasma ions, introduced into said chamber for bombarding said target by said electric potential gradient; and
an elongated magnet, scanning at a constant speed on the back side of said target reciprocately.

6. The pre-sputter of claim 5, wherein the pressure of the chamber is 1 to 10 mm torr by using a vacuum pump.

7. The pre-sputter of claim 5, wherein the scanning speed of the elongated magnet is 140 mm/s to 200 mm/s.

8. The pre-sputter of claim 5, wherein the scanning speed is 160 mm/s.
